(19) United States
(12) Patent Application Publication
(10) Pub. No.: US 2025/0254827 A1
(43) Pub. Date: Aug. 7, 2025

(54) WEDGE-SHAPED MANIFOLD MICROCHANNEL HEAT SINK WITH MICRO PIN FINS

(71) Applicant: XI'AN JIAOTONG UNIVERSITY, Xi'an (CN)

(72) Inventors: Jinjia WEI, Xi'an (CN); Zihuan MA, Xi'an (CN); Chengyu HU, Xi'an (CN); Xinyu JI, Xi'an (CN); Xiaoping YANG, Xi'an (CN)

(21) Appl. No.: 19/190,628

(22) Filed: Apr. 26, 2025

(30) Foreign Application Priority Data
Jan. 20, 2025 (CN) 202510083285.8

(51) Int. Cl. H05K 7/20

(52) U.S. Cl. CPC H05K 7/20272; H05K 7/2039

(57) ABSTRACT

A wedge-shaped manifold microchannel heat sink with micro pin fins, including a first cover plate, a second cover plate, a manifold substrate and a microchannel substrate that are sequentially arranged from top to bottom. The first cover plate is provided with a first inlet channel. The second cover plate is provided with a second inlet channel and a first outlet channel. The manifold substrate is provided with a third inlet channel and a second outlet channel. The microchannel substrate is provided with a plurality of rows of micro pin fins. A microchannel is formed between any two adjacent rows of micro pin fins.

### CROSS-REFERENCE TO RELATED APPLICATIONS

This application claims the benefit of priority from Chinese Patent Application No. 202510083285.8, filed on Jan. 20, 2025. The content of the aforementioned application, including any intervening amendments made thereto, is incorporated herein by reference in its entirety.

### TECHNICAL FIELD

This application relates to heat dissipation and cooling for electronic chips, and more particularly to a wedge-shaped manifold microchannel heat sink with micro pin fins.

### BACKGROUND

As electronic devices evolve towards higher power density and enhanced performance, the heat generated during operation increases significantly, leading to elevated operation temperature that will compromise the performance stability, service life and safety. Effective cooling technology has become critical for ensuring reliable operation of electronic devices, especially in high heat-flux environments such as data centers, 5G communications, aerospace and electric vehicles. Traditional natural cooling methods are insufficient, and thus it is urgent to develop an efficient and reliable thermal management solution to address these increasingly severe heat dissipation challenges.

Microchannel liquid-cooled heat sinks offer a high surface-area-to-volume ratio, enabling highly-efficient heat transfer and exhibiting remarkable heat dissipation performance. Furthermore, compared to the single-phase liquid cooling, flow boiling leverages both the sensible and latent heat of the working fluid, further enhancing the heat transfer coefficient and achieving higher cooling efficiency. However, due to the long flow path, traditional microchannel heat sinks often suffer from large temperature gradient, high pressure drop, poor flow uniformity and unstable flow during the flow boiling. These limitations hinder further improvement in heat dissipation capacity and efficiency, thereby restricting the application of microchannel heat sinks.

### SUMMARY

An object of the disclosure is to provide a wedge-shaped manifold microchannel heat sink with micro pin fins to address the technical problems of uneven flow distribution, poor temperature uniformity, high pressure drop and unstable flow in the traditional microchannel heat sinks.

Technical solutions of the present disclosure are described as follows.

A wedge-shaped manifold microchannel heat sink with micro pin fins, comprising:
a first cover plate;
a second cover plate;
a manifold substrate; and
a microchannel substrate;
wherein the first cover plate, the second cover plate, the manifold substrate and the microchannel substrate are sequentially arranged from top to bottom;
the first cover plate is provided with a first inlet channel; the second cover plate is provided with a second inlet channel and a first outlet channel; the manifold substrate is provided with a third inlet channel and a second outlet channel; the microchannel substrate is provided with a plurality of rows of micro pin fins; and a microchannel is formed between any two adjacent rows among the plurality of rows of micro pin fins;
the first inlet channel, the second inlet channel, the third inlet channel and the microchannel are sequentially communicated from top to bottom; and
the microchannel, the second outlet channel and the first outlet channel are sequentially communicated from bottom to top.

In some embodiments, the first inlet channel comprises a coolant inlet, a first groove and a second groove; the first groove is configured to distribute a coolant; and the coolant inlet, the first groove and the second groove are communicated in sequence;

the coolant inlet is provided on a side surface of the first cover plate; the first groove and the second groove are provided on a lower surface of the first cover plate; the coolant inlet is configured as a circular hole; and the second groove is configured as a rectangular groove; and

the first groove is configured as a tapered diverging groove; and a first end of the first groove is configured to fit the coolant inlet, and a second end of the first groove is configured to fit the second groove, wherein the first end of the first groove is smaller than the second end of the first groove in terms of width.

In some embodiments, the second inlet channel comprises a plurality of first wedge-shaped channels penetrating through the second cover plate in a thickness direction of the second cover plate; and
the plurality of first wedge-shaped channels are evenly distributed in a width direction of the second cover plate; a width of a flow cross-section of each of the plurality of first wedge-shaped channels is configured to decrease in a flow direction of a coolant; and the plurality of first wedge-shaped channels are located directly below the second groove.

In some embodiments, the first outlet channel comprises a wedge-shaped groove group, a third groove and a coolant outlet; and the wedge-shaped groove group, the third groove and the coolant outlet are communicated in sequence;
the wedge-shaped groove group is provided on a lower surface of the second cover plate; the third groove is configured to penetrate through the second cover plate in the thickness direction of the second cover plate; and the coolant outlet is provided on a side surface of the second cover plate; and
the wedge-shaped groove group comprises a plurality of wedge-shaped grooves evenly distributed in the width direction of the second cover plate; the plurality of wedge-shaped grooves and the plurality of first wedge-shaped channels are arranged alternately, and each of the plurality of wedge-shaped grooves is spaced apart from adjacent first wedge-shaped channels; and a width of a flow cross-section of each of the plurality of wedge-shaped grooves is configured to increase in the flow direction of the coolant.

In some embodiments, the third inlet channel comprises a plurality of second wedge-shaped channels penetrating through the manifold substrate in a thickness direction of the manifold substrate; and the plurality of second wedge-shaped channels are evenly distributed in a width direction of the manifold substrate; and
a width of a flow cross-section of each of the plurality of second wedge-shaped channels is configured to decrease in the flow direction of the coolant; and the plurality of second wedge-shaped channels are located directly below the plurality of first wedge-shaped channels.

In some embodiments, the second outlet channel comprises a plurality of third wedge-shaped channels penetrating through the manifold substrate in the thickness direction of the manifold substrate; and the plurality of third wedge-shaped channels are evenly distributed in the width direction of the manifold substrate;
the plurality of third wedge-shaped channels are arranged spaced apart from the plurality of second wedge-shaped channels; and
a width of a flow cross-section of each of the plurality of third wedge-shaped channels is configured to increase in the flow direction of the coolant; and the plurality of third wedge-shaped channels are located below the plurality of wedge-shaped grooves.

In some embodiments, the microchannel substrate is provided with a fourth groove; the plurality of rows of micro pin fins are arranged in a rectangular array within the fourth groove; and the microchannel is located directly below the plurality of second wedge-shaped channels and the plurality of third wedge-shaped channels.

In some embodiments, the first cover plate, the second cover plate and the manifold substrate are each made of a non-metallic material; the microchannel substrate is made of silicon nitride, silicon, copper or aluminum; and the first cover plate, the second cover plate, the manifold substrate and the microchannel substrate are boltedly connected.

In some embodiments, the first cover plate, the second cover plate, the manifold substrate and the microchannel substrate are each made of a metallic material; and the first cover plate, the second cover plate, the manifold substrate and the microchannel substrate are joined by brazing.

In some embodiments, the first cover plate, the second cover plate, the manifold substrate and the microchannel substrate are made of copper or aluminum.

Compared to the prior art, the present disclosure has the following beneficial effects.

1. The wedge-shaped manifold microchannel heat sink includes the manifold substrate. The manifold substrate is provided with the plurality of second wedge-shaped channels positioned directly above the microchannel. The plurality of second wedge-shaped channels are communicated with the microchannel. This configuration enables perpendicular fluid injection into the microchannel, generating a micro-jet effect that prevents flow dead zones, ensures uniform flow distribution, effectively shortens the flow path. This configuration is characterized by reduced pressure drop, lower thermal resistance and minimized risk of channel clogging.

2. The first wedge-shaped channels, the wedge-shaped grooves, the second wedge-shaped channels and the third wedge-shaped channels provided herein all adopt a wedge-shaped structure. In the fluid flow direction, an inlet section of the wedge-shaped structure narrows while an outlet section widens. As a result, in a wedge-shaped flow direction, a liquid volume gradually decreases while a gas volume gradually increases, facilitating the transition of two-phase flow patterns, enhancing fluid transport efficiency and vapor discharge efficiency, thereby improving heat transfer performance while reducing flow pressure drop.

3. The wedge-shaped manifold microchannel heat sink includes the microchannel substrate. The microchannel substrate is provided with the plurality of rows of micro pin fins. This configuration increases the heat transfer area and provides numerous nucleation sites, facilitating the early onset of boiling and significantly enhancing the critical heat flux. Additionally, while expanding the heat transfer area, the flow cross-section area of the working fluid is also enlarged, thereby reducing the pressure drop.

4. The wedge-shaped manifold microchannel heat sink provided herein ensures uniform fluid flow distribution across the flow channels, resulting in excellent temperature uniformity. Additionally, the presence of the micro pin fins disrupts the thermal boundary layer, enhances flow disturbance, and improves heat transfer performance.

### BRIEF DESCRIPTION OF THE DRAWINGS

In order to illustrate the technical solutions in the embodiments of the present disclosure or the prior art more clearly, the accompanying drawings needed in the description of the embodiments or prior art will be briefly described below. Obviously, presented in the accompanying drawings are only some embodiments of the present disclosure, and for those of ordinary skill in the art, other drawings can be obtained from the structures illustrated therein without making creative effort.

FIG. 1 is an exploded view of a wedge-shaped manifold microchannel heat sink with micro pin fins according to an embodiment of the present disclosure;

FIG. 2 is a cross-sectional view of the wedge-shaped manifold microchannel heat sink according to an embodiment of the present disclosure;

FIG. 3 is a bottom view of a first cover plate according to an embodiment of the present disclosure;

FIG. 4 is a top view of a second cover plate according to an embodiment of the present disclosure;

FIG. 5 is a bottom view of the second cover plate according to an embodiment of the present disclosure;

FIG. 6 is a structural diagram of a manifold substrate according to an embodiment of the present disclosure; and

FIG. 7 is a structural diagram of a microchannel substrate according to an embodiment of the present disclosure.

### DETAILED DESCRIPTION OF EMBODIMENTS

The technical solutions in the embodiments of the present disclosure will be described clearly and completely below in conjunction with the accompanying drawings. It is obvious that the described embodiments are merely some embodiments of the present disclosure, instead of all embodiments. Based on the embodiments in the present disclosure, all other embodiments obtained by those of ordinary skill in the art without making creative effort shall fall within the scope of the present disclosure defined by the appended claims.

In the description of the present disclosure, it should be understood that, the orientation or positional relationships indicated by terms, such as “center”, “up”, “down”, “front”, “back”, “left”, “right”, “vertical”, “horizontal”, “top”, “bottom”, “inner” and “outer” are based on the those shown in the accompanying drawings. These terms are solely for the convenience of describing the present disclosure in a simplified manner, and are not intended to indicate or imply that the devices or components must have specific orientations or be constructed and operated in such orientations. Therefore, these terms should not be understood as limitations of the present disclosure.

It should be noted that, unless otherwise expressly specified or limited, as used herein, the terms “mounted”, “connected” and “coupled” should be interpreted in a broad sense. For example, a connection can be a fixed connection, a detachable connection, or an integral connection. The specific meaning of these terms in the present disclosure can be understood by those skilled in the art based on the particular circumstances.

As used herein, terms such as “first” and “second” are only descriptive, and should not be construed as indicating or implying their relative importance or implicitly specifying the number of technical features indicated. As a result, a feature defined as “first” or “second” may include one or more of such features, either explicitly or implicitly. Unless otherwise specified, as used herein, the term “a plurality of” refers to two or more.

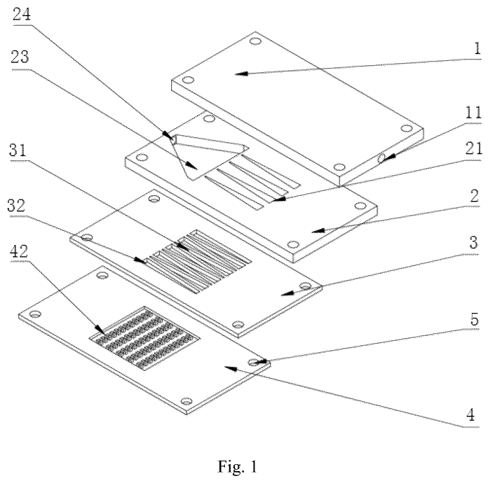

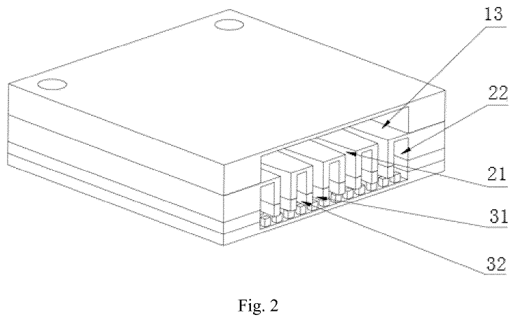

As shown in FIGS. 1-7, an embodiment of the present disclosure provides a wedge-shaped manifold microchannel heat sink with micro pin fins. The wedge-shaped manifold microchannel heat sink includes a first cover plate 1, a second cover plate 2, a manifold substrate 3 and a microchannel substrate 4. The first cover plate 1, the second cover plate 2, the manifold substrate 3 and the microchannel substrate 4 are sequentially arranged from top to bottom. The first cover plate 1, the second cover plate 2, the manifold substrate 3 and the microchannel substrate 4 are all rectangular plates. Four corners of each rectangular plate are each provided with a positioning hole 5 to facilitate the installation and fixation of the manifold microchannel heat sink.

The first cover plate 1 is provided with a first inlet channel. The second cover plate 2 is provided with a second inlet channel and a first outlet channel. The manifold substrate 3 is provided with a third inlet channel and a second outlet channel. The microchannel substrate 4 is provided with a plurality of rows of micro pin fins 42. A microchannel 43 is formed between any two adjacent rows among the plurality of rows of micro pin fins 42. The first inlet channel, the second inlet channel, the third inlet channel and the microchannel 43 are sequentially communicated from top to bottom. The microchannel 43, the second outlet channel and the first outlet channel are sequentially communicated from bottom to top.

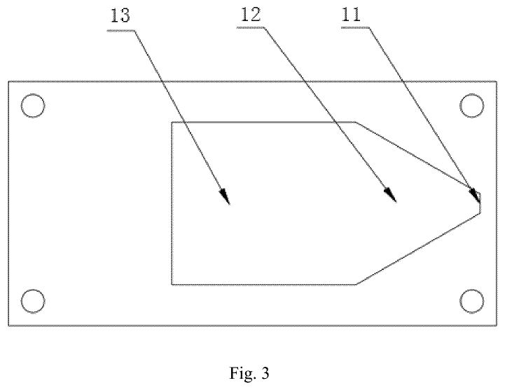

As shown in FIGS. 1 and 3, the first inlet channel includes a coolant inlet 11, a first groove 12 and a second groove 13. The first groove 12 is configured to distribute a coolant. The coolant inlet 11, the first groove 12 and the second groove 13 are communicated in sequence. The coolant inlet 11 is provided on the right side surface of the first cover plate 1. The first groove 12 and the second groove 13 are provided on a lower surface of the first cover plate 1. The first groove 12 and the second groove 13 both have equal groove depths. The coolant inlet 11 is configured as a circular hole. The second groove 13 is configured as a rectangular groove. The first groove 12 is configured as a tapered diverging groove. A first end of the first groove 12 is configured to fit the coolant inlet 11, and a second end of the first groove 12 is configured to fit the second groove 13. The first end of the first groove 12 is smaller than the second end of the first groove 12 in terms of width. In this manner, the coolant flows from the coolant inlet 11 into the first groove 12 and is subsequently distributed into the second groove 13. The presence of a tapered diverging structure of the first groove 12 enables more uniform distribution of the coolant within the second groove 13.

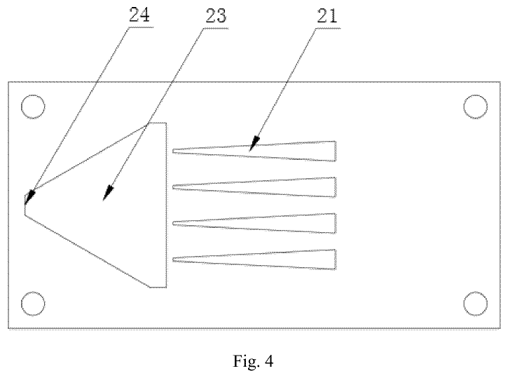

As shown in FIGS. 1 and 4, the second inlet channel is provided directly below the second groove 13. The second inlet channel includes a plurality of first wedge-shaped channels 21 penetrating through the second cover plate 2 in a thickness direction of the second cover plate 2. In this embodiment, the number of the first wedge-shaped channels 21 is four. The plurality of first wedge-shaped channels 21 are evenly distributed in a width direction of the second cover plate 2. A width of a flow cross-section of each of the plurality of first wedge-shaped channels 21 is configured to decrease in a flow direction of a coolant, meaning that the inlet passage becomes progressively narrower. By means of the plurality of first wedge-shaped channels 21, the flow distribution through the second cover plate 2 becomes more uniform. Compared with conventional microchannel heat sinks, this configuration effectively shortens the flow path, reduces pressure drop and thermal resistance and minimizes the risk of channel clogging.

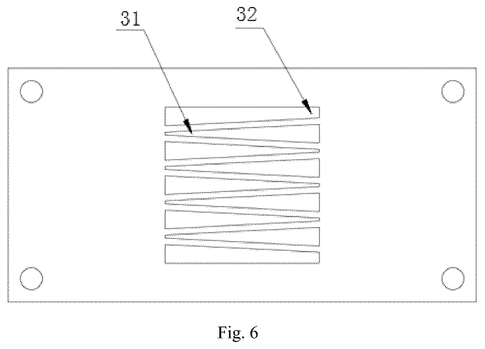

As shown in FIG. 6, the third inlet channel is located directly below the plurality of first wedge-shaped channels 21. The third inlet channel includes a plurality of second wedge-shaped channels 31 penetrating through the manifold substrate 3 in a thickness direction of the manifold substrate 3. In this embodiment, the number of the second wedge-shaped channels 31 is four. The plurality of second wedge-shaped channels 31 are evenly distributed in a width direction of the manifold substrate 3. A width of a flow cross-section of each of the plurality of second wedge-shaped channels 31 is configured to decrease in the flow direction of the coolant. In this way, the decreasing flow cross-section in the flow direction of the coolant is further maintained, which not only ensures uniform flow distribution but also enables the coolant to be injected vertically, generating a micro-jet effect and preventing the formation of flow dead zones.

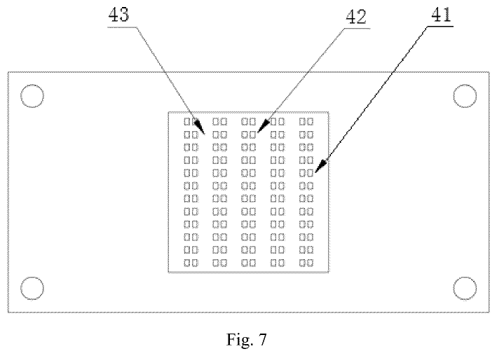

As shown in FIG. 7, the microchannel substrate 4 is provided with a fourth groove 41. The plurality of rows of micro pin fins 42 are arranged in a rectangular array within the fourth groove 41. The microchannel 43 is located directly below the plurality of second wedge-shaped channels 31 and a plurality of third wedge-shaped channels 32.

The microchannel substrate 4 is the primary component for enhancing heat transfer. The presence of the plurality of rows of micro pin fins 42 increases the contact area between the coolant and the solid material, thereby expanding the heat transfer area. This configuration provides numerous nucleation sites, which helps advance the onset of boiling and significantly improves the critical heat flux. Additionally, the secondary channels between the plurality of rows of micro pin fins 42 increase the flow cross-section area of the working fluid, providing space for the development of two-phase flow and preventing gas blockage, thereby reducing the pressure drop. As a result, the microchannel substrate 4 achieves higher heat transfer efficiency with lower pressure drop.

As shown in FIG. 6, the second outlet channel is provided directly above the microchannel 43. The second outlet channel includes the plurality of third wedge-shaped channels 32 penetrating through the manifold substrate 3 in the thickness direction of the manifold substrate 3. The plurality of third wedge-shaped channels 32 are evenly distributed in the width direction of the manifold substrate 3. The plurality of third wedge-shaped channels 32 are arranged spaced apart from the plurality of second wedge-shaped channels 31. A width of a flow cross-section of each of the plurality of third wedge-shaped channels 32 is configured to increase in the flow direction of the coolant.

The second wedge-shaped channels 31 and the third wedge-shaped channels 32 form a plurality of microchannel cooling units within the manifold microchannel heat sink, effectively shortening the flow path and providing advantages such as reduced pressure drop, lower thermal resistance and minimized risk of channel clogging. The flow is evenly distributed within each microchannel cooling unit, ensuring a nearly consistent convective heat transfer coefficient, which helps maintain temperature uniformity across the cooled device. This prevents stress concentration caused by temperature differences, thereby reducing the risk of device damage. The cooperation between the micro pin fins 42 and the microchannels 43 allows fluid communication between different microchannel cooling units, ensuring relatively stable and uniformly distributed flow velocity. Additionally, the presence of the micro pin fins 42 disrupts the thermal boundary layer, increases flow disturbance, and enhances heat transfer performance.

The manifold substrate 3 effectively isolates the upper coolant, preventing the coolant collected in a third groove 23 from directly contacting the microchannel substrate 4. This avoids temperature non-uniformity in the microchannel substrate 4.

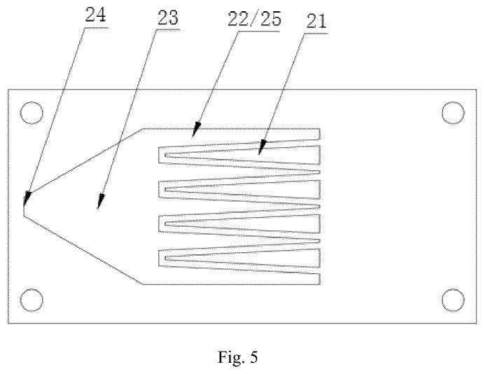

As shown in FIGS. 1 and 5, the first outlet channel includes a wedge-shaped groove group 22, the third groove 23 and a coolant outlet 24. The wedge-shaped groove group 22, the third groove 23 and the coolant outlet 24 are communicated in sequence. The wedge-shaped groove group 22 is provided on a lower surface of the second cover plate 2. The third groove 23 is configured to penetrate through the second cover plate 2 in the thickness direction of the second cover plate 2. The coolant outlet 24 is provided on the left side surface of the second cover plate 2.

The wedge-shaped groove group 22 is located directly above the second outlet channel. The wedge-shaped groove group 22 includes a plurality of wedge-shaped grooves 25 evenly distributed in the width direction of the second cover plate 2. In this embodiment, the number of wedge-shaped grooves 25 is five. The plurality of wedge-shaped grooves 25 and the plurality of first wedge-shaped channels 21 are arranged alternately, and each of the plurality of wedge-shaped grooves 25 is spaced apart from adjacent first wedge-shaped channels 21. The third groove 23 is configured as a triangular channel. The coolant outlet 24 is located at an apex of the left side of the third groove 23. The wedge-shaped grooves 25 are configured to align with the third wedge-shaped channels 32, providing a larger discharge path for the two-phase coolant after heat exchange.

Additionally, the wedge-shaped groove group 22 and the third wedge-shaped channels 32 are each configured as a wedge-shaped structure. By means of the above wedge-shaped structures, the liquid flow and the gas flow increases, the outlet channels gradually widen in the flow direction of the coolant. This design promotes the transition of the two-phase flow, enhances fluid delivery efficiency and vapor discharge efficiency, improves heat transfer performance, and reduces flow pressure drop.

The first cover plate 1, the second cover plate 2 and the manifold substrate 3 are each made of a non-metallic material such as transparent acrylic, while the microchannel substrate 4 can be made of materials such as silicon nitride, silicon, copper or aluminum. The first cover plate 1, the second cover plate 2, the manifold substrate 3 and the microchannel substrate 4 are boltedly connected, making the structure suitable for general atmospheric-pressure coolants.

The first cover plate 1, the second cover plate 2, the manifold substrate 3 and the microchannel substrate 4 are each made of a metallic material such as copper or aluminum. The first cover plate 1, the second cover plate 2, the manifold substrate 3 and the microchannel substrate 4 are joined by brazing. This structure is suitable for coolants with relatively high pressure.

A working principle of the present disclosure is as follows.

The second groove 13 is aligned with the second inlet channel. The coolant sequentially flows through the coolant inlet 11 on the first cover plate 1, the first groove 12, the second groove 13, the first wedge-shaped channels 21, the second wedge-shaped channels 31, and then enters the microchannel substrate 4 vertically. The manifold substrate 3 is in close contact with the microchannel substrate 4. After heat exchange occurs in the microchannel substrate 4, the coolant flows vertically upward through the third wedge-shaped channels 32 into the wedge-shaped grooves 25, and is subsequently discharged through the third groove 23 and the coolant outlet 24 in sequence. This process completes one heat exchange cycle.

In summary, the manifold microchannel heat sink provided herein optimizes and improves upon conventional microchannel heat sinks, offering advantages such as enhanced heat transfer capability, improved flow distribution uniformity, better temperature homogeneity and reduced pressure drop. Furthermore, the manifold microchannel heat sink is characterized by a simple manufacturing process, readily available materials and suitability for commercial production.

Described embodiments are merely illustrative, and are not intended to limit the scope of the present disclosure. It should be understood that various modifications, changes and replacements made by those skilled in the art without departing from the spirit of the disclosure shall fall within the scope of the present disclosure defined by the appended claims.

What is claimed is:

1. A wedge-shaped manifold microchannel heat sink with micro pin fins, comprising:
a first cover plate;
a second cover plate;
a manifold substrate; and
a microchannel substrate;
wherein the first cover plate, the second cover plate, the manifold substrate and the microchannel substrate are sequentially arranged from top to bottom;
the first cover plate is provided with a first inlet channel; the second cover plate is provided with a second inlet channel and a first outlet channel; the manifold substrate is provided with a third inlet channel and a second outlet channel; the microchannel substrate is provided with a plurality of rows of micro pin fins; and a microchannel is formed between any two adjacent rows among the plurality of rows of micro pin fins;
the first inlet channel, the second inlet channel, the third inlet channel and the microchannel are sequentially communicated from top to bottom; and
the microchannel, the second outlet channel and the first outlet channel are sequentially communicated from bottom to top.

2. The wedge-shaped manifold microchannel heat sink according to claim 1, wherein the first inlet channel comprises a coolant inlet, a first groove and a second groove; the first groove is configured to distribute a coolant; and the coolant inlet, the first groove and the second groove are communicated in sequence;
the coolant inlet is provided on a side surface of the first cover plate; the first groove and the second groove are provided on a lower surface of the first cover plate; the coolant inlet is configured as a circular hole; and the second groove is configured as a rectangular groove; and
the first groove is configured as a tapered diverging groove; and a first end of the first groove is configured to fit the coolant inlet, and a second end of the first groove is configured to fit the second groove, wherein the first end of the first groove is smaller than the second end of the first groove in terms of width.

3. The wedge-shaped manifold microchannel heat sink according to claim 2, wherein the second inlet channel comprises a plurality of first wedge-shaped channels penetrating through the second cover plate in a thickness direction of the second cover plate; and
the plurality of first wedge-shaped channels are evenly distributed in a width direction of the second cover plate; a width of a flow cross-section of each of the plurality of first wedge-shaped channels is configured to decrease in a flow direction of a coolant; and the plurality of first wedge-shaped channels are located directly below the second groove.

4. The wedge-shaped manifold microchannel heat sink according to claim 3, wherein the first outlet channel comprises a wedge-shaped groove group, a third groove and a coolant outlet; and the wedge-shaped groove group, the third groove and the coolant outlet are communicated in sequence;
the wedge-shaped groove group is provided on a lower surface of the second cover plate; the third groove is configured to penetrate through the second cover plate in the thickness direction of the second cover plate; and the coolant outlet is provided on a side surface of the second cover plate; and
the wedge-shaped groove group comprises a plurality of wedge-shaped grooves evenly distributed in the width direction of the second cover plate; the plurality of wedge-shaped grooves and the plurality of first wedge-shaped channels are arranged alternately, and each of the plurality of wedge-shaped grooves is spaced apart from adjacent first wedge-shaped channels among the plurality of first wedge-shaped channels; and a width of a flow cross-section of each of the plurality of wedge-shaped grooves is configured to increase in the flow direction of the coolant.

5. The wedge-shaped manifold microchannel heat sink according to claim 4, wherein the third inlet channel comprises a plurality of second wedge-shaped channels penetrating through the manifold substrate in a thickness direction of the manifold substrate; and the plurality of second wedge-shaped channels are evenly distributed in a width direction of the manifold substrate; and
a width of a flow cross-section of each of the plurality of second wedge-shaped channels is configured to decrease in the flow direction of the coolant; and the plurality of second wedge-shaped channels are located directly below the plurality of first wedge-shaped channels.

6. The wedge-shaped manifold microchannel heat sink according to claim 5, wherein the second outlet channel comprises a plurality of third wedge-shaped channels penetrating through the manifold substrate in the thickness direction of the manifold substrate; and the plurality of third wedge-shaped channels are evenly distributed in the width direction of the manifold substrate;
the plurality of third wedge-shaped channels are arranged spaced apart from the plurality of second wedge-shaped channels; and
a width of a flow cross-section of each of the plurality of third wedge-shaped channels is configured to increase in the flow direction of the coolant; and the plurality of third wedge-shaped channels are located below the plurality of wedge-shaped grooves.

7. The wedge-shaped manifold microchannel heat sink according to claim 6, wherein the microchannel substrate is provided with a fourth groove; the plurality of rows of micro pin fins are arranged in a rectangular array within the fourth groove; and the microchannel is located directly below the plurality of second wedge-shaped channels and the plurality of third wedge-shaped channels.

8. The wedge-shaped manifold microchannel heat sink according to claim 7, wherein the first cover plate, the second cover plate and the manifold substrate are each made of a non-metallic material; the microchannel substrate is made of silicon nitride, silicon, copper or aluminum; and the first cover plate, the second cover plate, the manifold substrate and the microchannel substrate are boltedly connected.

9. The wedge-shaped manifold microchannel heat sink according to claim 7, wherein the first cover plate, the second cover plate, the manifold substrate and the microchannel substrate are each made of a metallic material; and the first cover plate, the second cover plate, the manifold substrate and the microchannel substrate are joined by brazing.

10. The wedge-shaped manifold microchannel heat sink according to claim 9, wherein the first cover plate, the second cover plate, the manifold substrate and the microchannel substrate are made of copper or aluminum.
